(19) United States
(12) Patent Application Publication
(10) Pub. No.: US 2007/0029550 A1
(43) Pub. Date: Feb. 8, 2007

(54) LIQUID CRYSTAL DISPLAY APPARATUS

(76) Inventors: Norihiro Yoshida, Fukaya-shi (JP); Akio Murayama, Fukaya-shi (JP); Takeshi Yamaguchi, Kumagaya-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/458,562

(22) Filed: Jul. 19, 2006

(30) Foreign Application Priority Data
Aug. 5, 2005 (JP) 2005-228375

(51) Int. Cl. H01L 29/04

(52) U.S. Cl. 257/59

(57) ABSTRACT

A liquid crystal display apparatus comprises a liquid crystal display panel including a first substrate containing a color filter including a plurality of coloring layers, a second substrate arranged opposite to the first substrate and including a display surface on an opposite side to the first substrate and a liquid crystal layer held between the first substrate and the second substrate, and a circular polarization element arranged opposite to the display surface of the second substrate.

### CROSS-REFERENCE TO RELATED APPLICATIONS

This application is based upon and claims the benefit of priority from prior Japanese Patent Application No. 2005-228375, filed Aug. 5, 2005, the entire contents of which are incorporated herein by reference.

### BACKGROUND OF THE INVENTION

1. Field of the Invention

The present invention relates to a liquid crystal display apparatus.

2. Description of the Related Art

Generally, liquid crystal display apparatus comprises an array substrate, an opposite substrate arranged opposite to the array substrate with a predetermined gap therebetween, a liquid crystal layer held between the substrates, a color filter formed on the array substrate or the opposite substrate, and a backlight unit. The array substrate and opposite substrate each has a display region at a central portion. The color filter is formed in the display region. The color filter includes coloring layers of red, green and blue. The array substrate and opposite substrate are adhered to each other by their peripheral portions with a sealing member. A liquid crystal intake is formed in a section of the sealing member. After the liquid crystal is injected through the intake, the intake is sealed with a sealant, and thus the liquid crystal layer is prepared.

Color display active matrix drive liquid crystal display apparatus includes an array substrate. The array substrate include a plurality of signal lines and scanning lines arranged in matrix. Further, a thin film transistor (to be referred to as “TFT” hereinafter) with a channel layer made of, for example, amorphous silicon (a-Si) is provided in the vicinity of each of the intersections where the signal lines and scanning lines cross. Each of the TFTs is connected to a pixel electrode formed on the substrate. An alignment film is formed on pixel electrode and the substrate.

For example, as indicated in Jpn. Pat. Appln. KOKAI Publication No. 11-258635, a color filter, a black matrix that prevents the leakage of light from the gap between pixel electrodes, an opposite electrode and an alignment film are formed on a substrate of the opposite substrate. The black matrix is a thin film made of a material having a low reflection coefficient, such as a thin film that uses chromium oxide or black resin, and it is designed to prevent the reflection of external light. Further, the black matrix is provided at a position opposing to the signal lines, scanning lines and TFTs. The signal lines, scanning lines and TFTs are made of materials having high reflection coefficients. However, when the signal lines, scanning lines and TFTs are exposed to external light, the black matrix shuts the reflection light from the signal lines, scanning lines and TFTs, and therefore the leakage of light can be prevented. With this effect, the black matrix contributes to improvement of the contrast property of the liquid crystal display apparatus. The liquid crystal layer is formed between the array substrate and the opposite substrate, and thus the liquid crystal display apparatus is structured.

Apart from the liquid crystal display apparatus provided with a color filter on its opposite substrate as described above, recently, another type of liquid crystal display apparatus has been developed, which has such a structure that a color filter is provided on the array substrate to form a COA (color filter on array) structure, thereby obtaining a high opening efficiency rate.

As described above, when the COA structure is employed, a black matrix is not formed on the opposite substrate. With this structure, when the signal lines, scanning lines and TFTs are exposed to external light, the external light cannot shut the reflection light from the signal lines, scanning lines and TFTs. As a result, when a black image is displayed in a bright environment, the reflecting rate of the external light is increased and the contrast is lowered. Thus, the appearance of the image is deteriorated and the display quality is lowered.

The present invention has been achieved in consideration of the above point, and the object thereof is to provide a liquid crystal display apparatus having an excellent display quality.

### BRIEF SUMMARY OF THE INVENTION

In order to achieve the above-described object, according to an aspect of the present invention, there is provided a liquid crystal display apparatus comprising: a liquid crystal display panel including a first substrate containing a color filter including a plurality of coloring layers, a second substrate provided to oppose the first substrate and including a display surface on an opposite side to the first substrate and a liquid crystal player interposed between the first substrate and the second substrate; and

a circular polarization element provided to oppose the display surface of the second substrate.

Additional objects and advantages of the invention will be set forth in the description which follows, and in part will be obvious from the description, or may be leaned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view of a liquid crystal display apparatus according to the first embodiment of the present invention;

FIG. 2 is a cross sectional view of the liquid crystal display apparatus;

FIG. 3 is a plan view schematically showing the wiring structure of the array substrate shown in FIGS. 1 and 2;

FIG. 4 is a plan view of the liquid crystal display apparatus;

FIG. 5 is a diagram illustrating the optical path of external light entering the liquid crystal display;

FIG. 6 is a diagram showing the difference in liquid crystal injection time between a case where a light shield section is formed in the opposition region of the liquid crystal apparatus and a case where it is not; and

FIG. 7 is a diagram showing the difference in contrast between a case where a display mode and a polarization element located on an outer surface of the liquid display apparatus are selected and a case where another mode and another element are selected.

### DETAILED DESCRIPTION OF THE INVENTION

A liquid crystal display apparatus according to the first embodiment of the present invention will now be described in detail with reference to accompanying drawings.

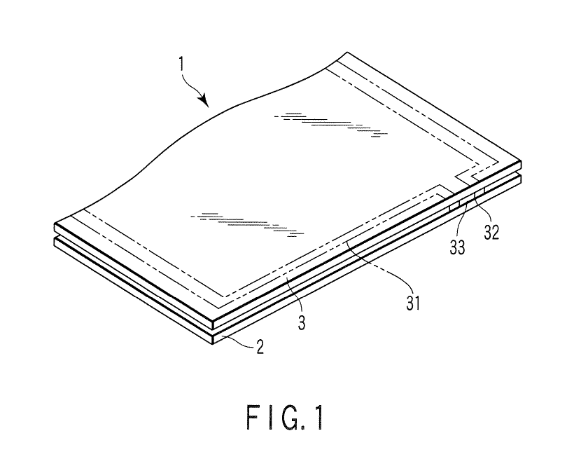

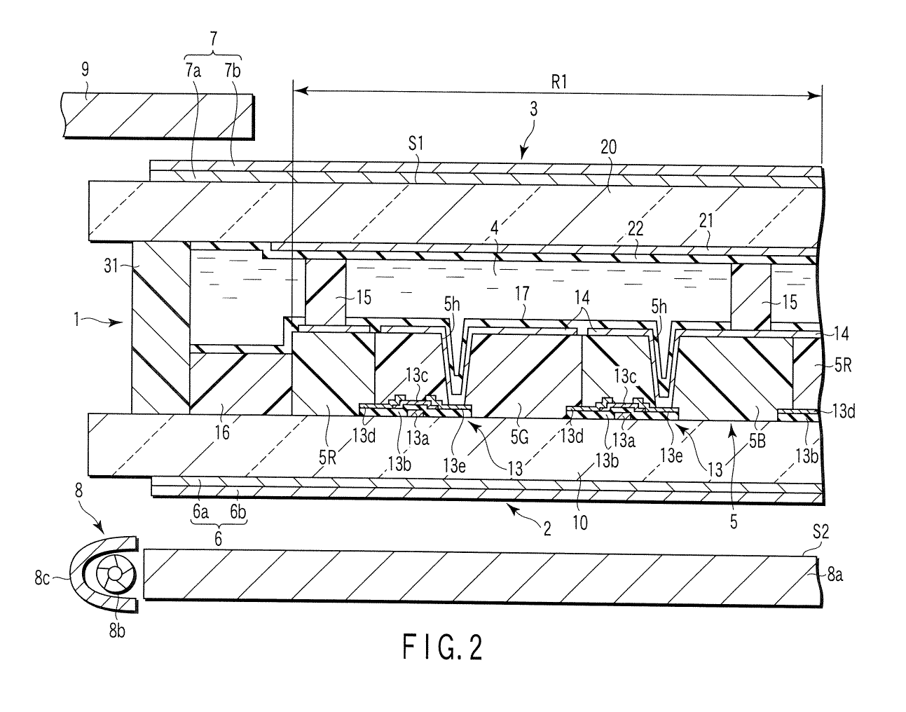

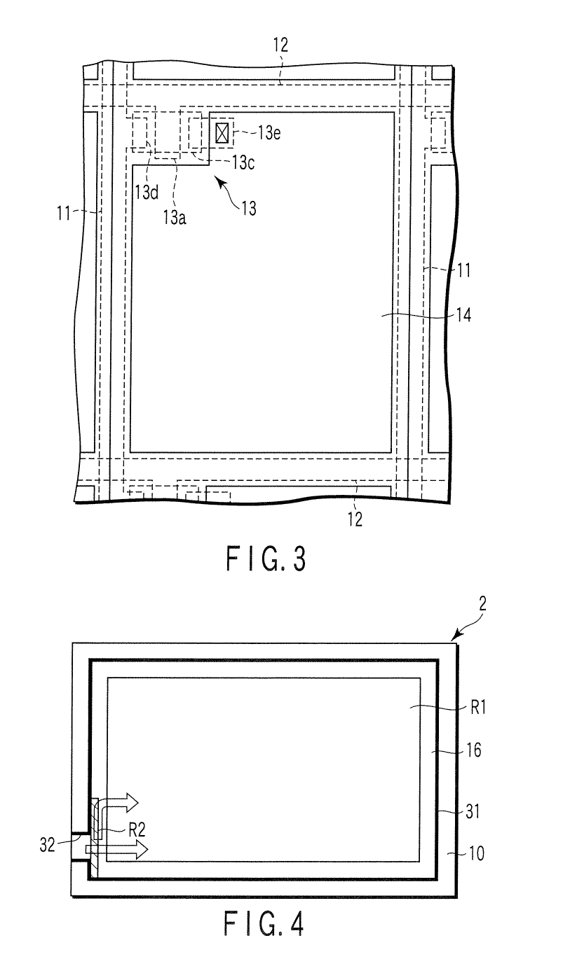

As can be seen in FIGS. 1 to 4, the liquid crystal display apparatus comprises a liquid crystal display panel 1, a first circular polarization element 6, a second circular polarization element 7, a backlight unit 8 and a bezel 9. The liquid crystal display panel 1 comprises an array substrate 2, which serves as a first substrate, an opposite substrate 3 arranged opposite to the array substrate with a predetermined gap therebetween, which serves as a second substrate, a liquid crystal layer 4 held between the array substrate 2 and the opposite substrate 3, and a color filter 5. The array substrate 2 and the opposite substrate 3 each have a rectangular display region R1 located at a central portion thereof. The display region R1 is designed to display images, and its size is 10″ in this embodiment.

The array substrate 2 includes a glass substrate 10, which serves as a transparent insulating substrate. A plurality of signal lines 11 and a plurality of scanning lines 12 are formed in matrix on the glass substrate 10. A switching element, for example, TFT 13, is provided at each of the intersecting sections between the signal lines 11 and scanning lines 12.

Each TFT 13 includes a gate electrode 13a formed by extending a portion of the respective scanning line 12, a gate insulating film 13b provided on the gate electrode, a semiconductor film 13c provided opposite to the gate electrode via the gate insulating film, a source electrode 13d connected to one of the regions of the semiconductor film and a drain electrode 13e connected to the other region of the semiconductor film. The source electrode 13d is connected to the respective signal line 11, whereas the drain electrode 13e is connected to a respective pixel electrode 14, which will be described later.

In the display region R1, each red coloring layer 5R, each green coloring layer 5R and each blue coloring layer 5B are arranged to be adjacent to each other side by side on the glass substrate 10, the respective signal line 11, the respective scanning line 12 and the respective TFT 13. The coloring layers 5R, 5G and 5B form a color filter 5. The coloring layers 5R, 5G and 5B are formed in stripe and they are arranged such that their edge portions overlap the respective signal line 11.

A plurality of pixel electrodes 14 made of a transparent conductive film such as ITO (indium tin oxide) are provided on the coloring layers 5R, 5G and 5B. Each of the pixel electrodes 14 is electrically connected to the drain electrode 13e of the respective TFT 13 via a contact hole 5h made in each coloring layer. A plurality of spacers, for example, columnar spacers 15, are formed on the pixel electrodes 14 at a predetermined density. An alignment film 17 is formed on the coloring layers 5R, 5G and 5B and the pixel electrodes 14. In this embodiment, the alignment film 17 is a vertically alignment film.

In the meantime, in an outer side of the display region R1, a rectangular frame shaped light shielding section 16 is formed on the glass substrate 10. The light shielding section 16 is formed all around the edge of the coloring layers in the display region R1. More specifically, the light shielding section 16 is formed at a section other than the counter region R2, which is one section opposing a liquid crystal intake 32, which will be later explained. The light shielding section 16 contributes to shielding of light leaking from the edge portion of the display region R1 and an inner side of the bezel 9, which will be later explained. It should be noted that the alignment film 17 is formed not only on the display region R1 but also at least the entire display region of the glass substrate 10 including the counter region R2.

The opposite substrate 3 includes a glass substrate 20, which is a transparent insulating substrate. An opposite electrode 21 made of a transparent conductive film such as of ITO is formed on the glass substrate 20. Further, although not shown in the figure, a transfer electrode which supplies common voltage from an array substrate electrode to counter electrode is formed on an edge portion of the glass substrate 20. In the display region R1, an alignment film 22 is formed on the opposite electrode 21. In this embodiment, the alignment film 22 is a vertically aligned film. It should be noted that the alignment film 22 is formed not only on the display region R1 but also at least the entire display region of the glass substrate 20 including the counter region R2. The opposite substrate 3 includes a display surface S1 on a side opposite to the array substrate 2.

The array substrate 2 and the opposite substrate 3 are arranged opposite to each other with a predetermined gap therebetween by the columnar spacers 15. The array substrate 2 and the opposite substrate 3 are bonded together with a sealing member 31 provided in the edge portions of both of the substrates. The sealing member 31 is provided on an outer circumference around the light shielding section 16. The liquid crystal layer 4 is held between the array substrate 2 and the opposite substrate 3. In this embodiment, the liquid crystal display panel 1 is a vertically alignment type. As described above, the alignment films 17 and 22 are formed on the counter region R2 as well, and therefore the liquid crystal molecules are treated to be vertically aligned in the counter region as well. The liquid crystal intake 32 formed in a section of the sealing member 31 is sealed with a sealant 33. Although it is not shown in the figure, transfer materials which conduct transfer electrode and counter electrode are formed on the transfer electrode. The transfer materials are made of a conductive material such as silver paste, and it is designed to apply a voltage between the array substrate 2 and the opposite electrode 21.

A first circular polarization element 6 is provided on an outer surface of the array substrate 2, and the first circular polarization element 6 serves as a circular polarization element having a circular polarization function. The first circular polarization element 6 is formed by stacking, for example, a λ/4 plate 6a and a polarization plate 6b one on another. The first circular polarization element 6 is provided between the array substrate 2 and the backlight unit 8. The second circular polarization element 7 is provided on a display surface S1 of the opposite substrate 3, and the second circular polarization element 7 serves as a circular polarization element having a circular polarization function. The second circular polarization element 7 is formed by stacking, for example, a λ/4 plate 7a and a polarization plate 7b. The first circular polarization element 6 and the second circular polarization element 7 are formed in the display region R1 and the counter region R2 as well.

The backlight unit 8 is provided on an outer surface side of the array substrate 2. The backlight unit 8 includes a light guiding plate 8a arranged opposite to the first circular polarization element 6, a light source 8b arranged opposite to an edge of one side of the light guiding plate, and a reflection plate 8c. The light guiding plate 8a includes a light emitting surface S2 that opposes the first circular polarization element 6. A frame-shaped bezel 9 is provided at a side of the display surface S1. The bezel 9 is provided at an outer side of the display region R1. The bezel 9 is placed so that its inner edge passes through the region opposing the light shielding section 16.

Next, the structure of the above-described liquid crystal display apparatus will now be described in more further detail, together with its manufacturing method.

First, signal lines 11, scanning lines 12 and TFTs 13, etc. are formed on a prepared glass substrate 10 by an ordinary manufacturing process such as repeating film formation and patterning.

Subsequently, a negative-type ultraviolet curing acryl resin resist in which, for example, a red pigment is dispersed, (to be called as red resist hereinafter) is applied as a coloring layer material on an entire surface of the glass substrate 10 using a spinner or the like. Next, a pattern is exposed to the red resist using a predetermined photomask. During the exposure, an ultraviolet ray having a wavelength of 365 nm is applied to the red resist at an exposure amount of 100 mJ/cm². The photomask used here includes stripe patterns of such a type that the ultraviolet ray is applied to sections to be colored in red, and patterns for contact holes 5h to connect the pixel electrodes 14 and the TFTs 13.

Next, the exposed red resist is developed for 20 seconds with a 1%-KOH aqueous solution. Thus, red coloring layers 5R having the contact holes 5h are formed using the photo-etching method.

Next, the glass substrate 10 on which the coloring layers 5R are formed is loaded in an oven, and the coloring layers 5R are baked and hardened at 200° C. for 60 minutes. After that, the glass substrate 10 is unloaded from the oven. In this manner, the formation of the coloring layers 5R are completed, and the completed layers have a thickness of about 3 μm.

Then, as in a similar manner to that of the coloring layers 5R, green coloring layers 5G having a thickness of about 3 μm and blue coloring layers 5B having a thickness of about 3 μm are formed by the photo-etching method in the order to be adjacent to each other, and contact holes 5h are formed in each coloring layers. Thus, the hardened coloring layers 5R, 5G and 5B are formed.

Next, ITO is deposited on the coloring layers 5R, 5G and 5B by, for example, a sputtering method. The deposited ITO is patterned to form a plurality of pixel electrodes 14 which respectively stack on the coloring layers and are respectively connected to the contact holes 5h.

After forming the pixel electrodes 14, a light shielding material such as a photosensitive acrylic black resin (to be referred to as black resist hereinafter) is applied on the glass substrate 10 using a spinner. After that, the black resist is dried at 90° C. for 10 minutes.

Next, a photomask is provided to oppose the black resist applied on the glass substrate 10, and UV ray is applied via the photomask to expose the black resist. During the exposure, an ultraviolet ray having a wavelength of 365 nm is applied to the black resist at an exposure amount of 300 mJ/cm². The photomask used here includes a pattern that oppose the region in which the columnar spacers 15 and the light shielding section 16 are to be formed.

Subsequently, the exposed black resist is developed with an alkali aqueous solution having a pH of 11.5, and then baked at 200° C. for 60 minutes. In this manner, the columnar spacers 15 and the light shielding section 16 are formed at the same time of the same material. Further, the columnar spacers 15 and the light shielding section 16 are formed to have the same height. The light shielding section 16 is formed in the region except for the counter region R2 opposing the liquid crystal intake 32.

Next, a vertically aligned film material, for example, a polyimide resin, is applied to have a thickness of 70 nm on the entire surface of the glass substrate 10 including the display region R1 and the counter region R2, and thus an alignment film 17 is obtained.

On the other hand, in order to manufacture the opposite substrate 3, first, the glass substrate 20 is prepared. ITO is deposited on the glass substrate 20 by, for example, the sputtering method, thereby forming the opposite electrode 21. Subsequently, a vertically aligned film material, for example, a polyimide resin, is applied to have a thickness of 70 nm on the entire surface of the glass substrate 10 including the display region R1 and the counter region R2, and thus an alignment film 22 is obtained.

Next, for example, a thermosetting sealing material 31 is printed along the circumference of the glass substrate 20, and then a transfer electrode is formed near the sealing material. The sealing material 31 is printed on all areas except for the region where the liquid crystal intake 32 is formed (a width of which is 1 cm). Subsequently, the array substrate 2 and the opposite substrate 3 are arranged opposite to each other with a predetermined gap therebetween by a plurality of columnar spacers 15, and the edges of the array substrate and the opposite substrate are attached together by the sealing material 31. After that, the sealing material 31 is heated to be hardened, and thus the array substrate 2 and the opposite substrate 3 are fixed to each other.

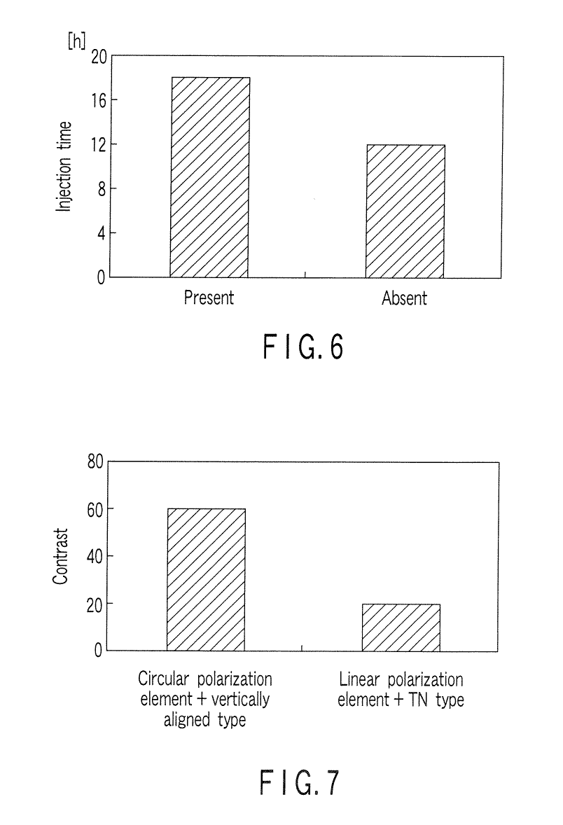

Then, with a vacuum injection method, an n-type liquid crystal, whose dielectric anisotropy is negative, is injected as the liquid crystal material from the liquid crystal intake 32 made in a section of the sealing member 31. After that, the liquid crystal intake 32 is sealed with a sealant 33 made of, for example, an ultraviolet curing resin. In the manner, liquid crystal is sealed in the gap between the array substrate 2 and the opposite substrate 3, and thus the liquid crystal layer 4 is formed. As shown in FIG. 6, in this embodiment, the injection time was 12 hours. The thickness of the liquid crystal layer 4 thus formed was about 3.5 μm.

Next, the first circular polarization element 6 is adhered to an outer surface of the array substrate 2, and the second circular polarization element 7 is adhered to an outer surface (display surface S1) of the opposite substrate 3. Further, the backlight unit 8, the bezel 9, etc. are mounted. Thus, the liquid crystal display apparatus is completed.

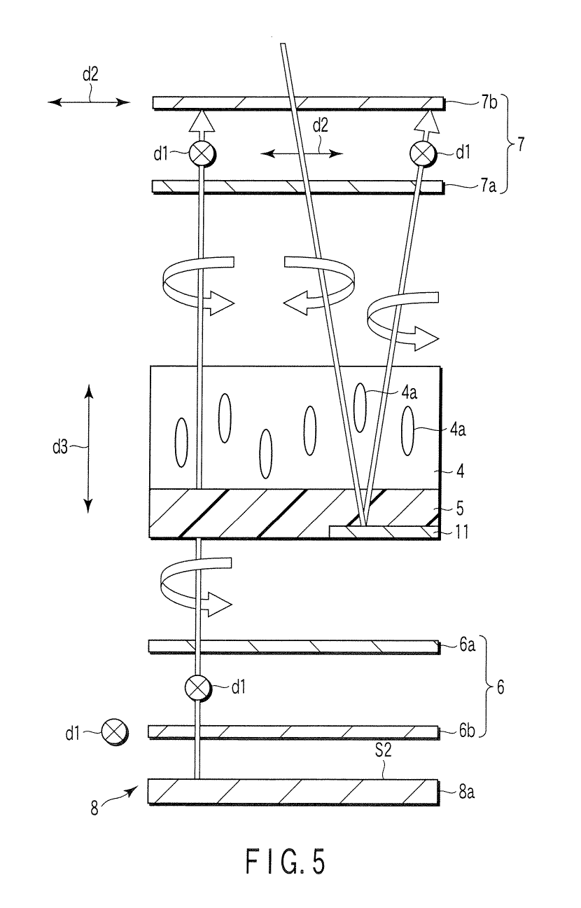

The following is an explanation on the optical properties of the liquid crystal display apparatus while a voltage is not applied between the pixel electrodes 14 and the opposite electrode 21 (that is, an electric field is not applied to the liquid crystal layer 4). Here, as shown in FIG. 5, the direction of the transmission-easy axis of the polarization plate 6b is a first direction d1. The direction of the transmission-easy axis of the polarization plate 7b is a second first direction d1, which is perpendicular to the first direction. The directions of the optical axes of the λ/4 plate 6a and λ/4 plate 7a make angles of 45 degrees with respect to the transmission-easy axes of the polarization plate 6b and the polarization plate 7b, respectively, and the directions of the optical axes cross normally with each other. The direction of the longitudinal axis of each liquid crystal molecules 4a of the liquid crystal layer 4 is substantially perpendicular to the surfaces of the alignment films 17 and 22, and is substantially parallel to a third direction that is normal to the first direction d1 and also to the second direction d2.

First, the optical path of light emitted from the backlight unit 8 will now be described.

When diffusing light is emitted from the light emission surface S2 of the backlight unit 8, the polarization plate 6b emits light as polarized light of the first direction d1 (linearly polarized light) to the λ/4 plate 6a, and the λ/4 plate 6a emits circular polarized light turned in a counter-clockwise direction (to be referred to as left-handed circular polarization hereinafter). Thus, the first circular polarization element 6 emits the left-handed circular polarized light to the liquid crystal layer 4 of the liquid crystal display panel 1. The liquid crystal layer 4 maintains the left-handed circular polarized light and emits it to the second circular polarization element 7.

The λ/4 plate 7a of the second circular polarization element 7 transmits the left-handed circular polarized light made incident from the liquid crystal layer 4, and emits the polarized light in the first direction d1 (linearly polarized light) to the polarization plate 7b. The polarized light of the first direction d1 normally crosses with the direction of the transmission-easy axis of the polarization plate 7b, and therefore it cannot pass through the polarization plate 7b. Therefore, the second circular polarization element 7 can shield the left-handed circular polarized light made incident from the liquid crystal layer 4 to the second circular polarization element 7.

Next, the light path of external light made incident on the liquid crystal display panel 1, which is reflected on a reflective part such as a signal line 11, will now be described.

When external light enters the second circular polarization element 7, the polarization plate 7b emits light as polarized light of the second direction d2 (linearly polarized light) to the λ/4 plate 7a, and the λ/4 plate 7a emits circular polarized light turned in a clockwise direction (to be referred to as right-handed circular polarization hereinafter). Thus, the second circular polarization element 7 emits the right-handed circular polarized light to the liquid crystal layer 4 of the liquid crystal display panel 1.

When the right-handed circular polarized light is made incident on the signal line 11, the polarized light is reflected by the signal line to become left-handed circular polarized light, which is out of phase by 180°, and it once again enters the second circular polarization element 7. The λ/4 plate 7a of the second circular polarization element 7 transmits the left-handed circular polarized light made incident from the liquid crystal layer 4, and emits the polarized light in the first direction d1 (linearly polarized light) to the polarization plate 7b. As described above, the polarized light of the first direction d1 normally crosses with the direction of the transmission-easy axis of the polarization plate 7b, and therefore it cannot pass through the polarization plate 7b. Therefore, the second circular polarization element 7 can shield the reflection light reflecting from the reflective parts of the liquid crystal display panel 1, such as not only the signal lines 11, but also the scanning lines, TFTs 13, etc.

As described above, while an electrical filed is not being applied to the liquid crystal layer 4, the liquid crystal display apparatus can shield the light emitted from the backlight unit 8 and the external light reflecting on the reflective parts such as the signal lines 11, etc. of the liquid crystal display panel 1. Therefore, an excellent black color display can be achieved.

The inventors of the present invention carried out measurement of the contrast while droving the backlight unit 8 and displaying an image using the liquid crystal display apparatus. During the measurement, the liquid crystal display apparatus was placed in an environment having an illumination of 500 lx (lux). As shown in FIG. 7, the contrast of the liquid crystal display apparatus was measured to be 60, which is a sufficiently high level. Thus, it was possible to prevent the decrease in contrast in a bright place.

According to the liquid crystal display apparatus of the first embodiment having the above-described structure, the second circular polarization element 7 is arranged opposite to the display surface S1 of the liquid crystal display panel 1. With this arrangement, while an electrical filed is not being applied to the liquid crystal layer 4, the liquid crystal display apparatus can shield the external light reflecting on the reflective parts such as the signal lines 11, etc. of the liquid crystal display panel 1.

The first circular polarization element 6 is arranged to be interposed between the array substrate 2 and the backlight unit 8. With this arrangement, while an electrical filed is not being applied to the liquid crystal layer 4, the liquid crystal display apparatus can shield the light emitted from the backlight unit 8.

Further, with the first circular polarization element 6, the polarized light transmitting the liquid crystal layer 4 becomes circular polarized light. Therefore, as compare to the case where the polarized light is linearly polarized light, the transmission rate of the polarized light during bright display (while applying electric field on the liquid crystal layer 4) can be improved, and therefore the brightness can be improved. As described above, an excellent black color display can be performed, and therefore a high-contrast display property can be obtained.

The first circular polarization element 6 and the second circular polarization element 7 are formed respectively in at least the display region R1 and the counter region R2 opposing the liquid crystal intake 32. Since the electrical field is never applied to the liquid crystal layer 4 of the counter region R2, the liquid crystal molecules 4a of the counter region R2 are aligned perpendicularly at all times. Thus, in the counter region R2, a block color is displayed at all times, and thus the light emitted from the backlight unit 8 is shielded. In this manner, the light emitted from the backlight unit 8 can be sufficiently between the edge of the display region R1 and the inner edge of the bezel 9.

As described above, the liquid crystal display apparatus having an excellent display quality can be obtained.

The shielding section 16 is not formed in the counter region R2. During the liquid crystal injection, liquid crystal injected and spread in the gap between the shielding portion 16 and the sealing member 31. Thus, the injection resistance during the liquid crystal injection can be suppressed, and thereby shortening the injection time.

In the above-described embodiment, the light shielding section 16 is formed in the edge portion of the display region R1; how ever the shielding section 16 is not essential and may be omitted. In such a case, the alignment films 17 and 22, the first circular polarization element 6 and the second circular polarization element 7 should be provided in the edge portion of the display region R1 as in the case of the liquid crystal display apparatus of the above-described embodiment, and thus the light emitted from the edge portion of the display region R1 and the inner side of the bezel 9 can be sufficiently shielded. Further, in this case, the injection resistance during the liquid crystal injection can be further suppressed, thereby making it possible to further shorten the injection time.

Next, the inventors of the present invention measured the contrast of the case where an image was displayed as in the case of the above-described embodiment using a liquid crystal display apparatus that has a structure different from that of the first embodiment, as Comparative Example 1. The liquid crystal display apparatus used here was made in a similar manner to that of the above-described first embodiment except that a TN (twisted nematic) type liquid crystal display panel 1 was used in place of the vertically aligned type and polarization plates having linearly polarizing functions were used in place of the first circular polarization element 6 and the second circular polarization element 7. (Note that the height of the columnar spacers 15 was set to about 5 μm.) The polarizing plates used here were subjected to surface treatments similar to those of the polarization plates 6b and 7b, respectively.

The inventors of the present invention measured the contrast in such a situation that the backlight unit 8 was driven and an image was displayed using the liquid crystal display apparatus of Comparative Example 1. During the measurement, the liquid crystal display apparatus was placed in an environment having an illumination of 500 lx (lux). As shown in FIG. 7, the contrast of the apparatus was measured to be 20, which was not very high. Thus, it was not possible to prevent the decrease in contrast in a bright place.

Next, the inventors of the present invention measured the liquid crystal injection time when a liquid crystal display apparatus having a structure different from that of the first embodiment was manufactured, as Comparative Example 2. The liquid crystal display apparatus used here was made in a similar manner to that of the above-described first embodiment except that the light shielding section 16 was formed on the counter region R2 as well.

The inventors of the present invention measured the injection time required for injecting the liquid crystal by a vacuum injection method. As shown in FIG. 6, the injection time was measured to 18 hours, which was 1.5 times longer than that of the first embodiment. It should be noted that the optical properties of the liquid crystal display apparatus of Comparative Example 2 was compared with those of the first embodiment, and no substantial difference was found.

Next, a liquid crystal display apparatus according to the second embodiment of the present invention will now be described. This embodiment has the same structure as that of the first embodiment except for the following points. Only the different points will now be described in detail.

In this embodiment, the liquid crystal display panel 1 is of a homogeneous alignment type. The alignment film 17 is formed in the following manner. That is, a horizontal alignment film material, for example, a polyimide resin, is applied to have a thickness of 70 nm on the entire surface of the glass substrate 10 including the display region R1 and the counter region R2. On the other hand, an alignment film 22 is formed in the following manner. That is, a horizontal alignment film material, for example, a polyimide resin, is applied to have a thickness of 70 nm on the entire surface of the glass substrate 20 including the display region R1 and the counter region R2.

In this embodiment, the alignment films 17 and 22 are horizontal alignment films. With regard to the alignment film treatment (rubbing), the alignment films 17 and 22 are subjected to alignment film treatments respectively such that the alignment films 17 and 22 are in opposite direction to each other when the array substrate 2 and the opposite substrate 3 are placed one on the other. The liquid crystal layer 4 is formed by injecting, as the liquid crystal material, p-type liquid crystal having a Δn=0.08 and a positive dielectric anisotropy.

The inventors of the present invention measured the contrast in such a situation that the backlight unit 8 was driven and an image was displayed using the liquid crystal display apparatus of this embodiment. During the measurement, the liquid crystal display apparatus was placed in an environment having an illumination of 500 lx (lux). The contrast of the apparatus was measured to be 60, which was similar to the case of the first embodiment, and sufficiently high. Thus, it was possible to prevent the decrease in contrast in a bright place. Further, for the black color display, it was confirmed that the liquid crystal display apparatus suppressed the leakage of the external light reflecting on the reflective parts such as the signal lines 11 of the liquid crystal display panel 1.

The liquid crystal display apparatus according to the second embodiment, which has the above-described structure, exhibits an excellent display quality and a shortened injection time.

It should be noted that the present invention is not limited to the above-described embodiments as they are, but they can be embodied, in practice, with different versions of structural elements as long as the essence of the invention does not fall out of the scope thereof. Further, some of the structural elements disclosed in the above embodiments can be re-combined appropriately to obtain various versions of the present invention. It is also possible that, for example, some of the structural elements are omitted from all of the structural elements presented in the embodiments. Further, structural elements from different embodiments may be combined appropriately. For example, the first circular polarization element 6 and the second circular polarization element 7 are made of the λ/4 plates 6a and 7a and the polarization plates 6b and 7b, but the constituents of these elements are not limited to these, but they may be arbitrary polarizing elements having circular polarization functions.

What is claimed is:

1. A liquid crystal display apparatus comprising:
a liquid crystal display panel including a first substrate containing a color filter including a plurality of coloring layers, a second substrate arranged opposite to the first substrate and including a display surface on an opposite side to the first substrate and a liquid crystal layer held between the first substrate and the second substrate; and
a circular polarization element arranged opposite to the display surface of the second substrate.

2. The liquid crystal display apparatus according to claim 1, further comprising:
a backlight unit arranged opposite to an outer surface of the first substrate, which illuminates the liquid crystal display panel; and
other circular polarization element provided between the first substrate and the backlight unit.

3. The liquid crystal display apparatus according to claim 1, wherein the liquid crystal display panel is of a vertically aligned type.

4. The liquid crystal display apparatus according to claim 3, wherein the liquid crystal layer is made of a liquid crystal material having a negative dielectric anisotropy.

5. The liquid crystal display apparatus according to claim 1, wherein the liquid crystal display panel comprises a display region which displays an image, a light shielding section formed in an edge of the display region and a sealing member formed in an outer side with respect to the light shielding section and having a liquid crystal intake; and
the light shielding section is formed in a region other than a part opposing the liquid crystal intake.

6. The liquid crystal display apparatus according to claim 5, wherein the circular polarization element and the other circular polarization element are formed in a region opposing the display region and the part opposing the liquid crystal intake.

7. The liquid crystal display apparatus according to claim 1, wherein the first substrate includes a plurality of wirings and a plurality of switching elements connected to the plurality of wirings,
the plurality of coloring layers includes a plurality of red, green and blue layers, and
the color filter is provided on the wirings and the switching elements.

8. A liquid crystal display apparatus comprising:
a liquid crystal display panel including a first substrate containing a color filter including a plurality of red, green and blue coloring layers, a second substrate arranged opposite to the first substrate and including a display surface on an opposite side to the first substrate and a liquid crystal layer held between the first substrate and the second substrate;
a backlight unit arranged opposite to an outer surface of the first substrate, which illuminates the liquid crystal display panel;
a circular polarization element arranged opposite to the display surface of the second substrate; and
other circular polarization element provided between the first substrate and the backlight unit.
